(19) United States
(12) Patent Application Publication
(10) Pub. No.: US 2026/0147283 A1
(43) Pub. Date: May 28, 2026

(54) OPTICAL COMPONENT, METHOD FOR INSTALLING THE OPTICAL COMPONENT, PROJECTION EXPOSURE APPARATUS

(71) Applicant: Carl Zeiss SMT GmbH, Oberkochen (DE)

(72) Inventors: Jasmin BIEHLER, Aalen (DE); Maria SCHLATHAUER, Neu-Ulm (DE); Vincent KOHL, Heidenheim (DE); Joerg HAUG, Heidenheim (DE); Florian VOGELMANN, Langenau (DE); Sebastian WEBER, Aalen (DE); Lutz RAMONAT, Paderborn (DE); Florian HENNE, Aalen (DE); Anissa Celina BOUALI, Aalen (DE); Christian KOERNER,, Muenchen (DE); Michael GUTKNECHT, Aalen (DE); Ferhat YILMAZ, Aalen (DE); Dieter BADER, Goeggingen (DE); Ilka SCHOENBORN, Aalen (DE)

(21) Appl. No.: 19/453,472

(22) Filed: Jan. 20, 2026

Related U.S. Application Data
(63) Continuation of application No. PCT/EP2024/067604, filed on Jun. 24, 2024.

(30) Foreign Application Priority Data
Jul. 20, 2023 (DE) 10 2023 206 872.9

(51) Int. Cl. G03F 7/00

(52) U.S. Cl. CPC G03F 7/70841; G03F 7/70825; G03F 7/70891; G03F 7/70991

(57) ABSTRACT

Provides is an optical component for EUV lithography, comprising a media-carrying pipe system for operation in a vacuum environment, wherein the media-carrying pipe system comprises at least one connection region between a metallic section and a section comprising or consisting of a silicon-containing substrate material having a coefficient of linear expansion of less than 3 ppm/K. The connection region is at least partially enclosed by an externally adjoining sealing device, wherein the sealing device comprises a sealing element and a fixing device attaching the sealing element to the connection region and wherein the sealing element comprises an elastomer.

### CROSS-REFERENCE TO RELATED APPLICATION

This is a Continuation of International Application PCT/EP2024/067604, which has an international filing date of Jun. 24, 2024, and the disclosure of which is incorporated in its entirety into the present Continuation by reference. This Continuation also claims foreign priority under 35 U.S.C. § 119(a)-(d) to and also incorporates by reference, in their entirety, German Patent Application DE 10 2023 206 872.9 filed on Jul. 20, 2023.

### FIELD

The techniques disclosed herein relate to an optical component for an EUV projection exposure apparatus, comprising a media-carrying pipe system for operation in a vacuum environment, wherein the media-carrying pipe system has at least one connection region between two sections and wherein the connection region is at least partially enclosed by an externally adjoining sealing device.

The disclosed techniques further relate to an EUV projection exposure apparatus having at least one optical component and to a method for installing an optical component.

### BACKGROUND

Projection exposure apparatuses for EUV lithography are used for the production of microstructured or nanostructured devices in microelectronics or microsystems technology. In order to be able to exactly produce structures with extremely small dimensions in the nanometre and micrometre ranges, a corresponding projection exposure apparatus must be capable of exactly imaging structures contained on a reticle onto a substrate, for example a wafer.

In projection exposure apparatuses designed for the EUV range, typically a wavelength of 13.5 nm is used to achieve a corresponding resolution on the substrate. Due to a lack of suitable light-transmissive materials in this wavelength range, mirrors are used as optical components for the imaging process. Due to the low transmission of radiation at wavelengths in the range of 13.5 nm through all gases, projection exposure apparatuses designed in this way operate in a vacuum environment.

Due to the required resolution for EUV projection exposure apparatuses, it is also desirable that the optical components of the EUV projection exposure apparatus exhibit as little temperature-related change in length as possible, with the result that, if possible, no deformations or only minor deformations, in particular of the optical surface, occur during operation. For this purpose, substrate materials which have an extremely small coefficient of linear expansion at an operating temperature are used for the optical components. For example, quartz glass, titanium-doped quartz glass or SiSiC are, therefore, used as substrate materials.

In order to operate the optical components as stably as possible at the operating temperature, they can be designed to be temperature-controllable. For example, German patent publication DE102017221388A1 describes how cooling structures in optical components can be obtained from the substrate materials described. These cooling structures partially have connecting pieces which are formed from the same substrate materials as the mirror substrate itself. For connection to an external media supply, these connecting pieces are connected to further pipe sections. Typically, such an external media supply is made of a metallic material, in particular stainless steel, aluminium, nickel, copper or their alloys.

For this purpose, internal sealing systems, for example, are known from the related art for connecting different pipe sections via flange surfaces. Examples of such flange-based sealing systems are described in DE102022203254B3, DE102020208496A1, and DE102020208200A1. If such a flange-based connection is not possible due to the design, it is necessary for the substrate materials of the optical components, such as quartz glass, titanium-doped quartz glass or SiSiC, to be connected directly, such as through welding, soldering, adhesively bonding or clamping, to metallic materials, such as stainless steel, aluminium, nickel, copper or their alloys.

However, external influences (e.g., those experienced during installation or operation) may cause such directly connected interfaces or connection regions between the substrate materials and the metallic materials to leak. Such fixed connections, particularly welded, soldered and adhesively bonded component, cannot be opened non-destructively. Repairing leaky connections may, therefore, necessitate re-applying the welding, soldering or adhesive bonding. Such a repair process is usually very time-consuming and associated with high costs. There is also a risk that the defect cannot be eliminated by the repair. If the cause of the leak is unknown, it may reoccur in the subsequent process even if the repair is successful. If such a leak of the optical component occurs during operation of the EUV projection exposure apparatus, there is also a risk that significant damage will occur to the EUV projection exposure apparatus due to operation of the apparatus in a vacuum environment.

It is, therefore, an object of the disclosed techniques to provide an improved optical component for an EUV projection exposure apparatus and a method for its installation, which circumvents the disadvantages described in the related art and is suitable for operation in a vacuum environment.

### SUMMARY

This object, among others, may be achieved in accordance with the features of the claims and embodiments described in this disclosure.

The optical component according to the disclosed techniques for EUV lithography has a media-carrying pipe system for operation in a vacuum environment, wherein the media-carrying pipe system comprises at least one connection region between a metallic section and a section consisting of a silicon-containing substrate material with a coefficient of linear expansion of less than 3 ppm/K. The connection region is at least partially enclosed by an externally adjoining sealing device, wherein the sealing device comprises a sealing element and a fixing device attaching the sealing element to the connection region, and wherein the sealing element comprises an elastomer.

The sealing device successfully eliminates existing and potential leaks in the connection region. Such sealing devices are known from the related art in the event of leaks for the repair of single-piece metallic pipeline systems (see e.g. WO15050428A1). The inventors for this disclosure have recognized that such sealing devices can be transferred to a media-carrying pipe system of an optical component with a connection region between a metallic section and a section constructed from, and in some cases constructed solely from, a silicon-containing substrate material with a coefficient of linear expansion of less than 3 ppm/K. Surprisingly, it could also be shown that the sealing device is suitable for use within a vacuum environment in which the optical components of EUV lithography operate, including an EUV plasma environment. In particular, a media-carrying pipe system refers to a pipe system with a circular, square or triangular cross section, but is not limited thereto.

According to a first embodiment of the optical component, the sealing device comprises a shielding unit. For example, the shielding unit is made of a metallic material, in particular aluminium, copper or stainless steel. In this case, the shielding unit can surround the sealing element and the fixing device, as a result of which the fixing device acts to directly attach the sealing element at the connection region. Likewise, the shielding unit can be arranged between the sealing element and the fixing device. In particular, if the shielding unit is designed in the form of a foil, a more stable attachment can be achieved by this arrangement, since the fixing device in this case also has an attaching effect for the shielding unit.

The shielding unit improves the usability of the sealing device in operation in a vacuum environment and/or an EUV plasma environment within the EUV projection exposure apparatus by encapsulating the sealing element or the sealing element and the fixing device. This may be particularly beneficial in regions of the EUV projection exposure apparatus having a very high cleanliness requirement and/or EUV plasma density. Using the shielding unit, the outgassing and a possible interaction with the EUV-induced plasma of the sealing device is advantageously prevented, decreased, or minimized.

According to one embodiment of the optical component, the sealing device has a mirror axis parallel to the connection region. This provides a symmetric design because the two connected sections are mirrored in the connection region. The symmetric design results in improved ease of installation, since the sealing element can be installed in a torsionally fixed manner. A more uniform compressibility of the sealing element relative to the connection region is also achieved.

According to one embodiment of the optical component, the media-carrying pipe system is a water-carrying pipe system for temperature control of the optical component. For the best possible imaging properties, it is often important that the substrate materials of the optical component according to the disclosed techniques have as small a change in length as possible during operation. For this purpose, substrate materials are used for the optical component which have an extremely small coefficient of linear expansion at an operating temperature. The water-carrying pipe system achieves a particularly effective temperature control of the optical component, especially in the operating temperature range.

According to an alternative embodiment of the optical component, the media-carrying pipe system is a gas-carrying pipe system. Thus, for example, a purge gas, such as nitrogen or hydrogen, can come into contact with individual regions of the optical component. These can provide and obtain a required cleanliness by purging within encapsulated volumes of the optical components. Alternatively, the purge gas can also be used for temperature control.

According to a particularly advantageous embodiment of the optical component, the connection region has a welded, soldered, adhesively bonded or clamped interface. These joining techniques are particularly suitable for joining metallic and silicon-containing substrate materials.

According to a further embodiment of the optical component, the metallic section comprises stainless steel, aluminium, nickel, or copper. These materials are particularly suitable for the formation of media-carrying pipe systems and are obtainable in a variety of ways. For example, they are characterized by a high resistance, in particular corrosion resistance, to the media used. They also have low outgassing and high resistance to an EUV plasma environment, which is advantageous for use in a vacuum environment. In addition, the materials are easy to clean, and therefore, are available in a correspondingly good cleanliness quality.

According to one embodiment of the optical component, the section comprising or consisting of a silicon-containing substrate material comprises quartz glass, titanium-doped quartz glass or SiSiC. These materials are particularly suitable as a substrate material of an optical component for EUV lithography. They sometimes have an extremely small coefficient of linear expansion in the operating temperature range of the optical component. In addition, these substrates can be coated with various materials for achieving reflectivity of EUV radiation.

According to a particularly advantageous embodiment of the optical component, the sealing element comprises a fluorine-containing polymer, for example a fluororubber or perfluororubber. These fluorine-containing polymers are characterized by good temperature resistance and are suitable for applications in contact with aggressive media and/or high purity requirements. Likewise, the sealing element may may be constructed from nitrile rubber, ethylene propylene diene rubber or a tetrafluoroethylene hexafluoropropylene copolymer.

According to one embodiment of the optical component, the fixing device comprises a stainless steel clamp. The design as a clamp means that the sealing element is compressed evenly at the connection region. A clamp is particularly suitable for a circular pipe geometry. The use of stainless steel makes the clamp suitable for use in a vacuum environment and easy to clean.

According to a particularly advantageous embodiment of the optical component, the clamp has an open thread for a screw connection. An open thread means a combination of a thread and a slotted hole separated at two connecting pieces of the clamp, as a result of which a screw used to attach the clamp is completely removable, creating a gap between the connecting pieces when the clamp is open. This causes the thread with the screw removed to be open. This further improves, in particular, the cleanability of the clamp. Alternatively, an ear-hose clamp can be used.

Furthermore, the disclosed techniques relate to a projection exposure apparatus for EUV lithography, which has at least one optical component according to the embodiments disclosed herein.

These techniques may provide the advantages already mentioned for the projection exposure apparatus. Further advantages and preferred features are evident from the description above and from the claims.

Furthermore, the disclosed techniques relate to a method for installing a sealing device for a connection region between a metallic section and a section comprising or consisting of a silicon-containing substrate material with a coefficient of linear expansion of less than 3 ppm/K of a media-carrying pipe system of an optical component for a vacuum environment.

In a first step of the method, a mounting cone is provided at an open end of a first section. The mounting cone enables a diameter difference of a sealing element and the first section of the media-carrying pipe system to be bridged. Advantageously, the mounting cone is placed on the section which has the smaller diameter of the two sections, so that the diameter difference to be bridged is as small as possible. The mounting cone can be made of, for example, stainless steel or an aluminium alloy, as well as of plastics such as polyoxymethylene (POM) or polyether ether ketone (PEEK).

In a second step of the method, a sealing element is provided. The sealing element consists, for example, of a fluororubber or perfluororubber. Likewise, the sealing element may consist of nitrile rubber, ethylene propylene diene rubber or a tetrafluoroethylene hexafluoropropylene copolymer.

In a third step of the method, the sealing element is placed on the mounting cone at the open end of the first section.

In a fourth step of the method, the sealing element is pulled over the first section, wherein the sealing element is moved to the connection region and encloses it. Since the elastic sealing element for the installation via the mounting cone has bridged, if necessary, a diameter difference with reference to the first section, the sealing element can rest against the connection region and surround it.

A fixing device is provided in a fifth step of the method. The fixing device may comprise a clamp made of stainless steel. Preferably, the clamp has an open thread according to the application, as a result of which it is easier to clean.

In a sixth step of the method, the fixing device is attached to the sealing element in such a way that the fixing device at least partially encloses and compresses the sealing element to obtain the sealing device.

According to one embodiment of the disclosed method, a shielding unit is provided in a seventh step. The shielding unit is made of aluminium, copper or stainless steel, for example. Likewise, the shielding unit can be designed in the form of a foil, as a result of which a more flexible adaptation to the sealing element is achieved. Subsequently, in an eighth step, the shielding unit is attached to the sealing device in such a way that the shielding unit encloses the sealing device at least partially, in particular completely. The shielding unit improves the usability of the sealing device and the optical component in operation in a vacuum environment and/or an EUV plasma environment within a projection exposure apparatus by at least partially encapsulating the sealing element and the fixing device. This prevents or minimizes outgassing and a possible interaction with the EUV-induced plasma of the sealing device.

According to an alternative embodiment of the disclosed method, the shielding unit is provided after the fourth step, pulling over of the sealing element, and is attached to the sealing element in such a way that it encloses the sealing element at least partially, in particular completely. The fixing device is then provided according to the fifth step and in an alternative step attached to the shielding unit and the sealing element underneath. In particular if the shielding unit is designed in the form of a foil, a more stable attachment can be achieved by this embodiment of the method, since the fixing device in this case also has an attaching effect for the shielding unit.

### BRIEF DESCRIPTION OF THE DRAWINGS

The techniques of this disclosure are to be elucidated in detail hereinafter by the drawings. In the drawings:

FIG. 1 shows an EUV projection exposure apparatus,

FIG. 2 shows an optical component according to the disclosed techniques for a projection exposure apparatus,

FIGS. 3A and 3B show a media-carrying pipe system of an optical component with a vacuum-compatible symmetric sealing device for a connection region of the pipe system,

FIGS. 4A and 4B show a media-carrying pipe system of an optical component with a vacuum-compatible asymmetric sealing device for a connection region of the pipe system,

FIGS. 5A and 5B show a media-carrying pipe system of an optical component having a vacuum-compatible symmetric sealing device comprising a shielding unit for a connection region of the pipe system,

FIGS. 6A and 6B show method steps for the installation of a sealing element as a constituent part of a sealing device for a media-carrying pipe system,

FIG. 7 shows a flowchart of an embodiment of the method disclosed herein, and

FIG. 8 shows a clamp as a fixing element for attaching a sealing element to a connection region with an open thread for a screw connection.

### DETAILED DESCRIPTION

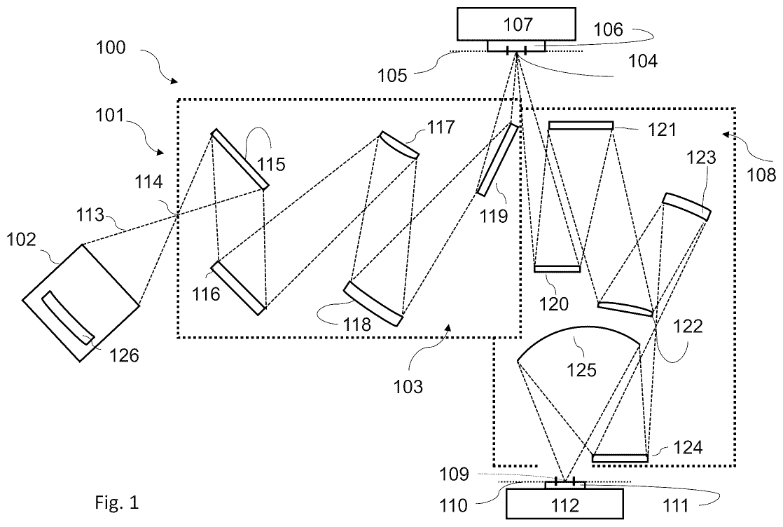

FIG. 1 shows as an example the basic structure of an EUV projection exposure apparatus 100 for semiconductor lithography.

An illumination system 101 of the EUV projection exposure apparatus 100 has, besides a radiation source 102, an illumination optical unit 103 for the illumination of an object field 104 in an object plane 105. A reticle 106 arranged in the object field 104 is illuminated, said reticle being held by a reticle holder 107, a portion of which is illustrated schematically. A projection optical unit 108 serves for imaging the object field 104 into an image field 109 in an image plane 110. A structure on the reticle 106 is imaged onto a light-sensitive layer of a wafer 111 which is disposed in the region of the image field 109 in the image plane 110 and which is held by a wafer holder 112 that is likewise illustrated in part.

The radiation source 102 can emit EUV radiation 113 having a wavelength in, for example, the range of between 5 nanometers and 30 nanometers, such as 13.5 nm. For this purpose, the radiation source has a collector mirror 126 as an optical component. Optically differently designed and mechanically adjustable optical elements are used for controlling the radiation path of the EUV radiation 113. In the case of the EUV projection exposure apparatus 100 illustrated in FIG. 1, the optical elements are in the form of adjustable mirrors in suitable embodiments that are mentioned merely by way of example hereinafter. Individual elements in the form of mirrors can comprise a plurality of segments with mutually separate optical partial surfaces.

The EUV radiation 113 generated from the radiation source 102 is aligned via the collector mirror 126 integrated in the radiation source 102 in such a way that the EUV radiation 113 passes through an intermediate focus in the region of an intermediate focal plane 114 before the EUV radiation 113 is incident on a field facet mirror 115. Downstream of the field facet mirror 115, the EUV radiation 113 is reflected by a pupil facet mirror 116. With the aid of the pupil facet mirror 116 and further optical components 117, 118, 119, field facets of the field facet mirror 115 are imaged into the object field 104. In this regard, see U.S. Pat. No. 9,411,241B2 accordingly.

The reticle 106 arranged in the object field 104 can be, for example, a reflective photomask, which has reflective and non-reflective, or at least less reflective, regions for producing at least one structure on the reticle 106. Alternatively, the reticle 106 can be a plurality of micro-mirrors, which are arranged in a one-dimensional or multi-dimensional component and which are optionally movable about at least one axis in order to set the angle of incidence of the EUV radiation on the respective mirror.

The reticle 106 reflects some of the beam path of the illumination optical unit 103 and shapes a beam path in the projection optical unit 108 that sends the information via the structure of the reticle 106 into the projection optical unit 108, said information producing an image representation of the reticle 106 or of a respective partial region thereof on the wafer 111 arranged in the image plane 110. The wafer comprises a semiconductor material, for example silicon, and is arranged on a wafer holder 112, which is also referred to as a wafer stage.

In the present example, the projection lens 108 has six reflective optical components 120 to 125, which are in the form of mirrors, in order to generate an image of the reticle 106 on the wafer 111. The number of mirrors in a projection lens 108 is typically between four and eight;. The number of mirrors may, however, be fewer or greater, greater, such as two mirrors or ten mirrors. Projection lenses are known from US2016/0327868A1 and DE102018207277A1.

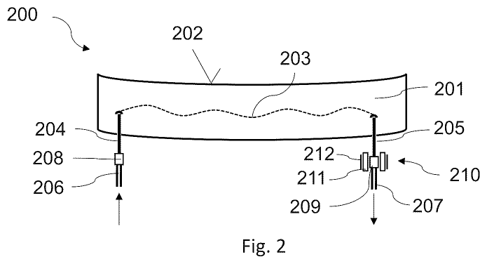

FIG. 2 shows an optical component 200 for the projection exposure apparatus 100, which component corresponds to, for example, the optical components 115-119 and 120-126 described in FIG. 1. In this case, the optical component 200 is designed in the form of a mirror, which comprises a mirror substrate 201 to which a reflective surface 202 has been applied. Quartz glass, titanium-doped quartz glass or SiSiC, which are typically characterized by a coefficient of linear expansion of less than 3 ppm/K, are used as the substrate material. In particular in the operating temperature range of the optical component 200, a sufficiently good dimensional stability is thereby achieved. The mirror substrate 201 can be temperature controlled in order to make the operating temperature stable even under a high power density of the EUV radiation 113. For this purpose, the mirror substrate 201 comprises a channel 203, through which media can flow. Gaseous and liquid substances can be used as media, in particular cooling media. To carry media in a targeted manner, the channel 203 has an input piece 204 and an output piece 205. In this case, the input piece 204 and the output piece 205 are formed from the same material as the mirror substrate 201, for example from quartz glass, titanium-doped quartz glass or SiSiC.

In order to connect the temperature-controlled mirror substrate 201 via the input piece 204 and the output piece 205 to an external media supply, the input piece 204 and the output piece 205 are connected to metallic pipe sections 206 and 207. The metallic pipe section 206 is designed as a feed and the metallic pipe section 207 is designed as a discharge for possible media transport (see arrow direction) and are constructed from, for example, stainless steel, aluminum, nickel, copper or their alloys. For the connection, connection regions 208 and 209 are formed between the input piece 204 and the metallic pipe section 206 and between the output piece 205 and the metallic pipe section 207. For example, the input piece 204 and/or the output piece 205 are soldered, welded or adhesively bonded to the metallic sections 206 or 207, respectively. Such a device is known, for example, from DE102017221388 A1.

However, there is a risk during operation or during installation that the connection regions 208 and/or 209 will be damaged or that leaks may occur due to, for example, corrosion. Since the optical component 200 is typically operated in a vacuum environment, the vacuum would be affected by such a leak.

Therefore, an externally adjoining sealing device 210 which at least partially encloses the connection region 209 is mounted on the connection region 209. The sealing device 210 comprises a sealing element 211 which comprises an elastomer, and a fixing device 212. Since FIG. 2 is a perspective sectional illustration of the connection region 209 and the sealing device 210 surrounds the connection region 209 rotationally symmetrically, the elements 211 and 212 of the sealing device 210 are shown to the left and right of the connection region 209.

The sealing element 211 is compressed by the fixing device 212 at the connection region 209 and in this case encloses at least leaking regions or potentially leaking regions of the connection region 209. In this case, the sealing element 211 is encapsulated at least partially against the environment by the fixing device 212. The potentially free regions of the sealing element 211 must therefore be suitable for use in a vacuum environment and, in particular, in an EUV plasma environment. Therefore, the sealing element 211 may be constructed from, for example, a fluororubber or perfluororubber. Likewise, the sealing element 211 may be constructed from nitrile rubber, ethylene propylene diene rubber or a tetrafluoroethylene hexafluoropropylene copolymer. The fixing device 212 can be designed as a clamp and be made of stainless steel. Preferably, the clamp has an open thread according to the application, as a result of which it is easier to clean.

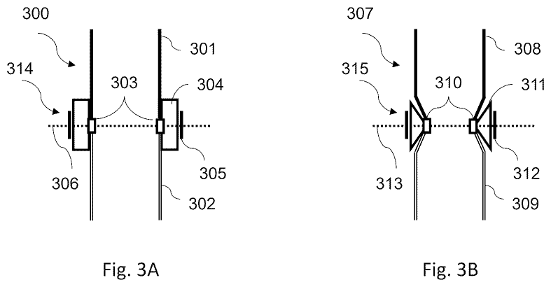

In the following text, various exemplary embodiments of media-carrying pipe systems, comprising a metallic section, a section constructed from a silicon-containing substrate material with a coefficient of linear expansion of less than 3 ppm/K, a connection region and a sealing device at least partially surrounding the connection region according to the techniques of the present disclosure are illustrated in FIGS. 3-5. The exemplary embodiments are part of an optical component for operation in a vacuum environment of EUV lithography, for example according to FIG. 2, which are not shown again individually for reasons of clarity.

FIGS. 3A and 3B show two embodiments 300, 307 of a media-carrying pipe system of an optical component for operation in a vacuum environment with a sealing device 314, 315. A metallic pipe section 302, 309 is each connected, for example welded, soldered, adhesively bonded or clamped, via a connection region 303, 310 to a pipe section 301, 308 consisting or comprising of a silicon-containing substrate material with a coefficient of linear expansion of less than 3 ppm/K. The connection region 303, 310 is each at least partially enclosed by the externally adjoining sealing device 314, 315, wherein the sealing device 314, 315 comprises a sealing element 304, 311 and a fixing device 305, 312. In this case, the sealing element 304, 311 is attached to the connection region 303, 310 by the fixing device 305, 312. For the best possible sealing effect, the shape of the sealing element 304, 311 is adapted in each case to the environment of the connection region 303, 310. With respect to possible materials of the two connected sections 301, 302, 308, 309, the sealing element 304, 311 and the fixing device 305, 312, the examples described in accordance with FIG. 2 apply analogously.

Characteristic of the embodiments 300, 307 according to FIGS. 3A and 3B is the symmetric design, which is manifested in each case by a mirror axis 306, 313 within the sealing devices 314, 315 parallel along the connection regions 303 or 310. Advantages of a symmetric design result in terms of improved ease of installation and as uniform a compression of the sealing element 304, 311 as possible with respect to the connection region 303, 310.

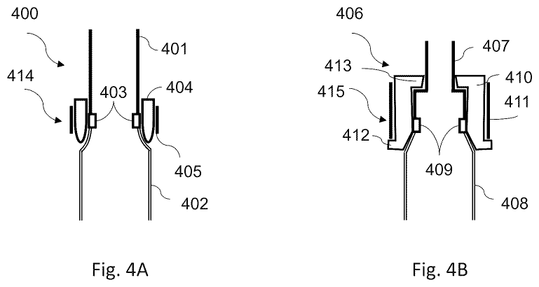

FIGS. 4A and 4B show two further embodiments 400, 406 of a media-carrying pipe system of an optical component for operation in a vacuum environment with a sealing device 414, 415. A metallic section 402, 408 is each connected, for example welded, soldered, adhesively bonded or clamped, via a connection region 403, 409 to a section 401, 407 comprising or consisting of a silicon-containing substrate material with a coefficient of linear expansion of less than 3 ppm/K. The connection region 403, 409 is each at least partially enclosed by the externally adjoining sealing device 414, 415, wherein the sealing device 414, 415 comprises a sealing element 404, 410 and a fixing device 405, 411. In this case, the sealing element 404, 410 is attached to the connection region 403, 409 by the fixing device 405, 411. With respect to possible materials of the two connected sections 401, 402, 407, 408, the sealing element 404, 410 and the fixing device 405, 411, the examples described in accordance with FIG. 2 apply analogously.

Characteristic of the embodiments 400, 406 according to FIGS. 4A and 4B is an asymmetric design of the sealing device 414, 415, which is manifested in each case by a lack of a mirror axis within the sealing devices 414, 415 parallel along the connection regions 403 or 409. If an asymmetric design is chosen due to the geometry of the sections to be connected, the sealing element 404, 410 may have a special marking to improve the ease of installation. For the best possible sealing effect, the shape of the sealing element 404, 410 for the asymmetric design is likewise adapted in each case to the environment of the connection region 403, 409. For better positioning and support of the sealing element 410 on the section 407 and the fixing device 411, it can comprise, as is shown in FIG. 4B, individually adapted webs 412, 413.

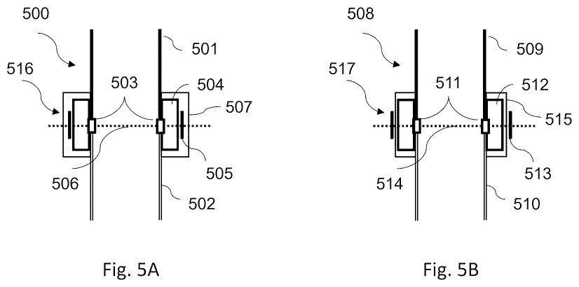

FIGS. 5A and 5B show two further embodiments 500, 508 of a media-carrying pipe system of an optical component for operation in a vacuum environment with a sealing device 516, 517. A metallic section 502, 510 is each connected, for example welded, soldered, adhesively bonded or clamped, via a connection region 503, 511 to a section 501, 509 comprising or consisting of a silicon-containing substrate material with a coefficient of linear expansion of less than 3 ppm/K. In this case, these embodiments 500, 508 have a symmetric design, which is manifested in each case by a mirror axis 506, 514 within the sealing devices 516, 517 parallel along the connection regions 503, 511. The connection region 503, 511 is each at least partially enclosed by the externally adjoining sealing device 516, 517, wherein the sealing device 516, 517 comprises a sealing element 504, 512 and a fixing device 505, 513. In this case, the sealing element 504, 512 is attached to the connection region 503, 511 by the fixing device 505, 513.

In addition to the embodiments of FIGS. 3A, 3B, 4A, and 4B, the embodiments 500, 508 each have a shielding unit 507, 515. According to FIG. 5A, the shielding unit 507 can surround the sealing element 504 and the fixing device 505, as a result of which the fixing device 505 acts to directly attach the sealing element 504 at the connection region 503. Likewise, as is shown in FIG. 5B, the shielding unit 515 may be arranged between the sealing element 512 and the fixing device 513. In particular if the shielding unit 515 is designed in the form of a foil, a more stable attachment can be achieved by this component, since the fixing device 513 in this case also has an attaching effect for the shielding unit 515.

The shielding unit 507, 515 improves the usability of the sealing device 516, 517 in operation in a vacuum environment and/or an EUV plasma environment within the projection exposure apparatus 100 by encapsulating the sealing element or the sealing element and the fixing device. This may be particularly important in regions of the projection exposure apparatus 100 having a very high cleanliness requirement and/or EUV plasma density. Using the shielding unit 507, 515, the outgassing and a possible interaction with the EUV-induced plasma of the sealing device 516, 517 is prevented or minimized. For this purpose, the shielding unit 507, 515 is made of, for example, aluminium, copper or stainless steel. The use of a shielding unit is also possible for an asymmetric design.

For the best possible sealing effect, the shape of the sealing element 504, 512 is adapted in each case to the environment of the connection region 503, 511. With respect to possible materials of the two connected sections 501, 502, 509, 510, the sealing element 504, 512 and the fixing device 505, 513, the examples described in accordance with FIG. 2 apply analogously.

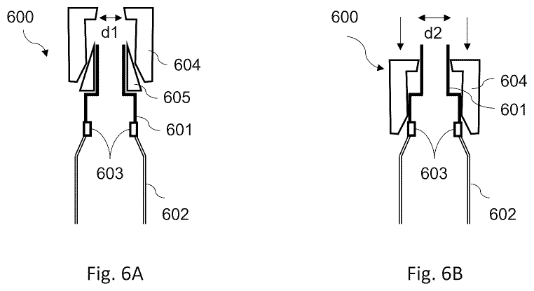

FIGS. 6A and 6B show two method steps for the installation of a sealing element 604 as a constituent part of a sealing device 210 for a media-carrying pipe system 600 of an optical component. In this case, the media-carrying pipe system 600 according to the disclosed techniques comprises a metallic section 602 and a section 601 of a silicon-containing substrate material with a coefficient of linear expansion of less than 3 ppm/K, which are connected, for example welded, soldered, adhesively bonded or clamped, by a connection region 603. Since the media-carrying pipe system 600 is designed for operation in a vacuum environment, and the connection region 603 has a risk of developing a leak during operation or during installation in preparation for operation, the connection region 603 of the media-carrying pipe system 600 is intended to be additionally protected by a sealing device.

For this purpose, as is shown in FIG. 6A, the sealing element 604, which typically consists of an elastomer, is guided with the aid of a mounting cone 605 over the first section 601 of the media-carrying pipe system 600. Advantageously, this is started with the pipe section of smaller diameter. In this case, the mounting cone 605 allows a continuous expansion of an inner diameter d1 of the sealing element 604 to an extended inner diameter d2. When the extended inner diameter d2 is reached, the mounting cone is removed in the direction of the pipe section 601 with the smaller inner diameter. As shown in FIG. 6B, the sealing element 604 thus expanded can be pulled over the first section 601, wherein the sealing element 604 is moved in the direction of the arrow to the connection region 603. Here, the sealing element 604 can be attached to the connection region 603 with a fixing device and, if necessary, a shielding unit (both not shown).

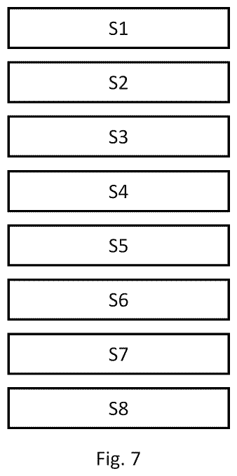

FIG. 7 shows a flowchart of an embodiment of the disclosed method for installing a sealing device 210, 314, 315, 414, 415, 516, 517 of a media-carrying pipe system 300, 307, 400, 406, 500, 508, 600 for the formation of the optical component 200. The method is described with reference to the illustrated media-carrying pipe systems 300, 307, 400, 406, 500, 508 of an optical component 200 and is applicable thereto.

In a first step S1, a mounting cone 605 is provided at an open end of a first section 601. The mounting cone 605 enables the bridging of a diameter difference of a sealing element 211, 304, 311, 404, 410, 504, 512, 604 and the first section of the media-carrying pipe system 300, 307, 400, 406, 500, 508, 600. Advantageously, the mounting cone 605 is placed on the section which has the smaller diameter of the two sections, so that the diameter difference to be bridged is as small as possible.

In a second step S2, a sealing element 211, 304, 311, 404, 410, 504, 512, 604 is provided. The sealing element 211, 304, 311, 404, 410, 504, 512, 604 comprises an elastomer, for example a fluororubber or perfluororubber. Likewise, the sealing element 211, 304, 311, 404, 410, 504, 512, 604 may comprise nitrile rubber, ethylene propylene diene rubber or a tetrafluoroethylene hexafluoropropylene copolymer.

In a third step S3, the sealing element 211, 304, 311, 404, 410, 504, 512, 604 is placed on the mounting cone 605 at the open end of the first section 601.

In a fourth step S4, the sealing element 211, 304, 311, 404, 410, 504, 512, 604 is pulled over the first section 601 and moved to a connection region 209, 303, 310, 403, 409, 503, 511, 603 to enclose it. Since the elastic sealing element 211, 304, 311, 404, 410, 504, 512, 604 for the installation is expanded starting from an inner diameter d1 to an inner diameter d2 via the mounting cone 605, the sealing element 211, 304, 311, 404, 410, 504, 512, 604 rests against and surrounds the connection region 209, 303, 310, 403, 409, 503, 511, 603.

In a fifth step S5, a fixing device 212, 305, 312, 405, 411, 505, 513 is provided. The fixing device 212, 305, 312, 405, 411, 505, 513 can comprise a clamp of stainless steel. Preferably, the clamp has an open thread according to the application, as a result of which it is easier to clean.

In a sixth step S6, the fixing device 212, 305, 312, 405, 411, 505, 513 is attached to the sealing element 211, 304, 311, 404, 410, 504, 512, 604 in such a way that the fixing device 212, 305, 312, 405, 411, 505, 513 at least partially encloses and compresses the sealing element 211, 304, 311, 404, 410, 504, 512, 604, as a result of which the sealing device 210, 314, 315, 414, 415, 516, 517 is obtained.

Preferably, a shielding unit 507 is provided in a seventh step S7. For example, the shielding unit 507 is made of aluminium, copper or stainless steel.

Preferably, in an eighth step S8, the shielding unit 507 is mounted on the sealing device 516 in such a way that the shielding unit 507 encloses the sealing device 516 at least partially, in particular completely. Using the shielding unit 507, the usability of the sealing device 516 in operation in a vacuum environment and/or an EUV plasma environment within a projection exposure apparatus 100 is improved by the sealing element 504 and the fixing device 505 being at least partially encapsulated. This prevents or minimizes outgassing as well as a possible interaction with the EUV-induced plasma of the sealing device 516.

In an alternative embodiment of the method according to the disclosed techniques, a shielding unit 515 is provided in a step S4.1, after step S4, and attached in a step S4.2 to a sealing element 512. In the following steps S5 and S6, the fixing device 513 is provided and attached to the shielding unit 515 and the sealing element 512 underneath. In particular, if the shielding unit 515 is designed as a foil, a more stable attachment can be achieved by this embodiment of the method, since the fixing device 513 in this case also has an attaching effect for the shielding unit 515.

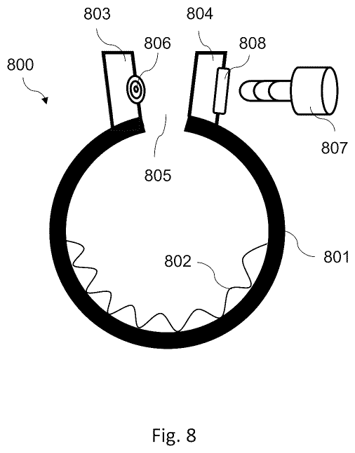

FIG. 8 shows an embodiment of a clamp 800 as a fixing element with an open thread 806 for a variant of the component according to the disclosed techniques. The clamp 800 is, for example, of stainless steel and encompasses an approximately circular main body 801, which further comprises a positioning aid 802 for improved fixation of a sealing element (not shown). Furthermore, the clamp 800 comprises two connection regions 803, 804, which are mounted on the upper region of the main body 801. In this case, a gap 805 is formed between the two connection regions 803, 804. Through the gap 805, the thread 806 arranged in the first connection region 803 is open in the dismantled state and thus freely accessible, for example, for cleaning. For fixing the clamp 800 to a sealing element, a screw 807 is guided through a slotted hole 808 of the second connection region until the screw 807 engages the thread 806 by way of a rotational movement. Thereby, the gap 805 decreases with continued rotational movement, and the clamp 800 can thereby fix a sealing element to a connection region (both not shown).

### LIST OF REFERENCE SIGNS

100 Projection exposure apparatus
101 Illumination system
102 Radiation source
103 Illumination optical unit
104 Object field
105 Object plane
106 Reticle
107 Reticle holder
108 Projection optical unit
109 Image field
110 Image plane
111 Wafer
112 Wafer holder
113 EUV radiation
114 Intermediate focal plane
115 Field facet mirror
116 Pupil facet mirror
117-119 Further mirrors of the illumination optical unit
120-125 Further optical elements of the projection optical unit
126 Collector mirror
200 Optical component
201 Mirror substrate
202 Reflective surface
203 Channel
204 Input piece
205 Output piece
206 Metallic pipe section
207 Metallic pipe section
208 Connection region
209 Connection region
210 Sealing device
211 Sealing element
212 Fixing device
300 Media-carrying pipe system of an optical component
301 Pipe section made of silicon-containing substrate material
302 Metallic pipe section
303 Connection region
304 Sealing element
305 Fixing device
306 Mirror axle
307 Media-carrying pipe system of an optical component
308 Pipe section made of silicon-containing substrate material
309 Metallic pipe section
310 Connection region
311 Sealing element
312 Fixing device
313 Mirror axle
314 Sealing device
315 Sealing device
400 Media-carrying pipe system of an optical component
401 Pipe section made of silicon-containing substrate material
402 Metallic pipe section
403 Connection region
404 Sealing element
405 Fixing device
406 Media-carrying pipe system of an optical component
407 Pipe section made of silicon-containing substrate material
408 Metallic pipe section
409 Connection region
410 Sealing element
411 Fixing device
412 Web
413 Web
414 Sealing device
415 Sealing device
500 Media-carrying pipe system of an optical component
501 Pipe section made of silicon-containing substrate material
502 Metallic pipe section
503 Connection region
504 Sealing element
505 Fixing device
506 Mirror axle
507 Shielding unit
508 Media-carrying pipe system of an optical component
509 Pipe section made of silicon-containing substrate material
510 Metallic pipe section
511 Connection region
512 Sealing element
513 Fixing device
514 Mirror axle
515 Shielding unit
516 Sealing device
517 Sealing device
600 Media-carrying pipe system of an optical component
601 Pipe section made of silicon-containing substrate material
602 Metallic pipe section
603 Connection region
604 Sealing element
605 Mounting cones
S1 First method step
S2 Second method step
S3 Third method step
S4 Fourth method step
S5 Fifth method step
S6 Sixth method step
S7 Seventh method step
S8 Eighth method step
S4.1 Alternative method step
S4.2 Alternative method step
800 Clamp
801 Main body
802 Positioning aid
803 First connection region
804 Second connection region
805 Gap
806 Thread
807 Screw
808 Slotted hole

What is claimed is:

1. An optical component for EUV lithography, comprising:
a media-carrying pipe system configured for operation in a vacuum environment, the media-carrying pipe system comprising:
a metallic section;
a section comprising a silicon-containing substrate material with a coefficient of linear expansion of less than 3 ppm/K; and
at least one connection region connecting the metallic section and the section comprising the silicon-containing substrate material;
wherein the at least one connection region is enclosed, at least partially, by an externally adjoining sealing device that comprises a sealing element and a fixing device attaching the sealing element to the at least one connection region; and
wherein the sealing element comprises an elastomer.

2. The optical component of claim 1, wherein the sealing device further comprises a shielding unit.

3. The optical component of claim 1, wherein the sealing device has a mirror axis parallel to the at least one connection region.

4. The optical component of claim 1, wherein the media-carrying pipe system is a water-carrying pipe system for temperature control of the optical component.

5. The optical component of claim 1, wherein the media-carrying pipe system is a gas-carrying pipe system.

6. The optical component of claim 1, wherein the at least one connection region has a welded, soldered, adhesively bonded or clamped interface.

7. The optical component of claim 1, wherein the metallic section comprises stainless steel, aluminium, nickel or copper.

8. The optical component of claim 1, wherein the section comprising a silicon-containing substrate material comprises quartz glass, titanium-doped quartz glass or SiSiC.

9. The optical component of claim 1, wherein the sealing element comprises a fluorine-containing polymer.

10. The optical component of claim 1, wherein the fixing device comprises a clamp of stainless steel.

11. The optical component of claim 10, wherein the clamp has an open thread for a screw connection.

12. A projection exposure apparatus, for EUV lithography comprising an optical component according to claim 1.

13. A method for installing a sealing device of a media-carrying pipe system of an optical component for a vacuum environment, the sealing device enclosing, at least partially, a connection region connecting a metallic section and a section comprising a silicon-containing substrate material with a coefficient of linear expansion of less than 3 ppm/K, the method comprising:
providing a mounting cone at an open end of a first section,
providing a sealing element,
placing the sealing element on the mounting cone at the open end of the first section,
pulling the sealing element over the first section, wherein the sealing element is moved to the connection region and encloses it,
providing a fixing device, and
forming the sealing device by attaching the fixing device to the sealing element such that the fixing device at least partially encloses and compresses the sealing element.

14. The method of claim 13, further comprising:
providing a shielding unit, and
attaching the shielding unit to the sealing device in such a way that the shielding unit encloses the sealing device at least partially.

15. The method of claim 13, further comprising:
providing a shielding unit, after the sealing element has been pulled over, that is attached to the sealing element such that it encloses the sealing element at least partially.
